(19) United States
(12) Patent Application Publication
(10) Pub. No.: US 2024/0048001 A1
(43) Pub. Date: Feb. 8, 2024

(54) APPARATUS AND METHOD FOR TRANSMITTING POWER WIRELESSLY

(71) Applicant: Hitachi-LG Data Storage Korea, Inc., Seoul (KR)

(72) Inventor: Cheol JIN, Seoul (KR)

(73) Assignee: Hitachi-LG Data Storage Korea, Inc., Seoul (KR)

(21) Appl. No.: 18/229,230

(22) Filed: Aug. 2, 2023

(30) Foreign Application Priority Data
Aug. 3, 2022 (KR) 10-2022-0096694

(51) Int. Cl. H02J 50/60; H02J 50/12; H02J 50/80; H02J 50/40

(52) U.S. Cl. CPC H02J 50/60; H02J 50/12; H02J 50/80; H02J 50/40

(57) ABSTRACT

The method of wirelessly transmitting power according to an embodiment may comprise performing an operation of analog ping on each of multiple coils of a primary coil; determining whether there is an object based on a result of the operation of analog ping; determining whether there is a receiving device including a secondary coil that can be coupled to the primary coil by magnetic induction by performing an operation of digital ping when it is determined that there is an object; and wirelessly transmitting power to a receiving device or stopping transmitting power thereto when it is determined that there is the receiving device.

### TECHNICAL FIELD

The present disclosure relates to an apparatus and method for wirelessly transmitting power, and, more particularly, to a method of detecting a foreign matter in a wireless charger which adopts multiple coils.

### BACKGROUND

With the development of communication and information processing technology, use of smart terminals such as a smart phone and the like has gradually increased and at present, a charging scheme generally applied to the smart terminals is a scheme that directly connects an adapter connected to a power supply to the smart terminal to charge the smart phone by receiving external power or connects the adapter to the smart terminal through a USB terminal of a host to charge the smart terminal by receiving USB power.

In recent years, in order to reduce inconvenience that the smart terminal needs to be directly connected to the adapter or the host through a connection line, a wireless charging scheme that wirelessly charges a battery by using magnetic coupling without an electrical contact has been gradually applied to the smart terminal.

There are several methods for wirelessly supplying or receiving electrical energy, representatively, an inductive coupling method based on electromagnetic induction and a resonance coupling method (that is electromagnetic resonance coupling method) based on an electromagnetic resonance phenomenon using a wireless power signal of a specific frequency.

In both methods, it is possible to secure stability of power transmission and increase transmission efficiency by exchanging data through the communication channel formed between a wireless charging apparatus and an electronic device such as a smart terminal. The inductive coupling method has a problem in that the transmission efficiency is lowered by the movement of the power receiving device while wirelessly receiving power, and the resonant coupling method has a problem in that power transmission is interrupted due to noise occurring in the communication channel.

When there is a metal foreign object such as a coin between a transmitting apparatus and a receiving device, power loss occurs and if the wireless transmission power is concentrated on the metal foreign object, there is a risk of overheating, which hinders stable power transmission. Therefore, a foreign object detection (FOD) function capable of detecting whether or not a metal foreign object is placed in a transmitting apparatus is necessarily implemented in a product to which a wireless charging standard of the inductive coupling method is applied.

In the meantime, in the case of general wireless chargers that are recently used, there is a problem in that charging is possible only with low power of, for example, 15 W or less, and a transmission distance is short, i.e., less than several millimeters. In addition, there is also a problem that transmission efficiency is reduced because a power receiving device moves on the surface of the interface of a power transmitting apparatus, that is, a wireless charger.

In order to improve the capability of transmitting power and the transmission distance of wireless chargers and expand the wireless charging area thereof, wireless chargers consisting of multiple coils, that is, wireless power transmitting apparatuses by inductive coupling in which a plurality of transmission coils are arranged to overlap each other instead of forming only one transmission coil have been released.

While a wireless charger employing multiple coils is carrying out the operation of detecting a foreign object based on an analog ping value, it may not properly detect a small foreign object. When a foreign object between the wireless charger and a power receiving device is not detected and wireless charging is performed, the temperature rises inevitably.

### SUMMARY

Taking such a situation into consideration, the objective of the present disclosure is to provide a method of effectively determining whether there is a foreign object in a power transmitting apparatus adopting multiple coils.

The method of wirelessly transmitting power in accordance with an embodiment of the present disclosure may comprise performing an operation of analog ping on each of multiple coils of a primary coil; determining whether there is an object based on a result of the operation of analog ping; determining whether there is a receiving device including a secondary coil that can be coupled to the primary coil by magnetic induction by performing an operation of digital ping when it is determined that there is an object; and wirelessly transmitting power to a receiving device or stopping transmitting power thereto when it is determined that there is the receiving device. The step of determining whether there is an object may comprise: a first step of determining whether there is an object based on an analog ping variation obtained for each coil by the operation of analog ping; and a second step of determining whether there is an object based on an analog ping sum variation obtained by adding up the analog ping variation for each coil when it is not determined that there is an object in the first step.

The wireless power transmitting apparatus in accordance with another embodiment of the present disclosure may comprise: a power conversion unit comprising an inverter for converting DC power to AC power and a resonant circuit including a primary coil consisting of multiple coils for transmitting power by being coupled, by magnetic induction, with a secondary coil of a receiving device; a measurement unit configured to measure an analog ping value as a result of an operation of analog ping; and a control unit configured to control the power conversion unit to perform the operation of analog ping on each of the coils of the primary coil, determine whether there is an object based on the analog ping value measured by the measurement unit, determine whether there is the receiving device by controlling the power conversion unit to perform an operation of digital ping when determining that there is an object, and control the power conversion unit to wirelessly transmit power to the receiving device or to stop power transmission when determining that there is the receiving device. The control unit may be further configured to determine whether there is an object based on an analog ping variation of each coil obtained by the operation of analog ping, and determine whether there is an object based on an analog ping sum variation obtained by adding up an analog ping variation of each coil when not determining that there is an object.

Therefore, it may be possible for a wireless charger employing multiple coils to effectively determine whether there is a metal foreign object between the charger and a power receiving device, so that, when power is transmitted wirelessly, it may be possible to prevent in advance the risk of a fire caused by excessive heat generation resulting from concentration of output on a metal foreign object.

### BRIEF DESCRIPTION OF THE DRAWINGS

FIG. 1 conceptually illustrates that power is wirelessly transmitted from a power transmitting apparatus to an electronic device.

FIG. 2 conceptually illustrates a circuit configuration of a power conversion unit of a transmitting module for wirelessly transmitting power in an electromagnetic induction scheme.

FIG. 3 illustrates a configuration for a wireless power transmitting module and a wireless power receiving module to send and receive power and messages.

FIG. 4 is a block diagram of a loop for controlling power transmission between a wireless power transmitting module and a wireless power receiving module.

FIG. 5 shows coil input and output observed when performing the operation of analog ping in which a signal of a resonant frequency is input to a coil to obtain an output voltage of the coil by an ADC.

FIG. 6 shows an operation of measuring a resonant frequency and an analog peak voltage of each coil while moving an object through a transmission coil consisting of multiple coils,

FIG. 7 shows a comparison of a peak voltage variation (analog ping variation) and an object detection level of each coil that have been measured by the operation in FIG. 6.

FIGS. 8A to 8C respectively show analog ping variations, object detection levels, and sections in which an object cannot be detected of first to third transmission coils.

FIG. 9 shows the variation of the sum of analog ping values of the first to third coils and an object detection level.

FIGS. 10A to 10C respectively show analog ping variations, resonance frequency variations, object detection levels for the analog ping variation, and object detection levels for the resonance frequency variation of the first to third transmission coils, which have been measured while moving an object as shown in FIG. 6.

FIG. 11 shows the configuration of a wireless power transmitting apparatus to which the embodiment of this disclosure is applied in blocks.

FIG. 12 is a flowchart illustrating an operation of a method for wirelessly transmitting power while detecting an object according to an embodiment of this disclosure.

### DETAILED DESCRIPTION

Hereinafter, an embodiment of an apparatus and method for transmitting power wirelessly according to this disclosure will be described in detail with reference to the accompanying drawings.

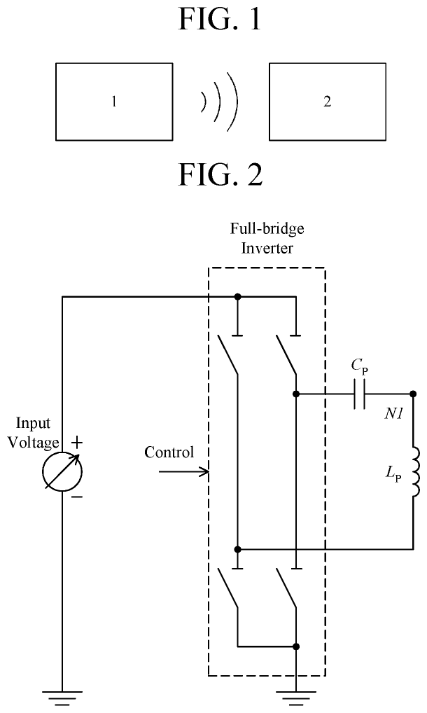

FIG. 1 conceptually illustrates that power is wirelessly transmitted from a wireless power transmitting apparatus to an electronic device.

The wireless power transmitting apparatus 1 may be a power transferring apparatus wirelessly transferring power required by a wireless power receiving device or an electronic device 2, or a wireless charging apparatus for charging a battery by wirelessly transferring power. Or the wireless power transmitting apparatus 1 may be implemented by one of various types of apparatuses transferring power to the electronic device 2 requiring power with non-contact.

The electronic device 2 may be operable by wirelessly receiving power from the wireless power transmitting apparatus 1 and charge a battery by using wirelessly received power. The electronic device that wirelessly receives power may include portable electronic devices, for example, a smart phone, a tablet computer, a multimedia terminal, an input/output device such as a keyboard, a mouse, a video or audio auxiliary device, a secondary battery, and the like.

Power may be wirelessly transmitted by an inductive coupling scheme based on an electromagnetic induction phenomenon by a wireless power signal generated by the wireless power transmitting apparatus 1. That is, resonance is generated in the electronic device 2 by the wireless power signal transmitted by the wireless power transmitting apparatus 1 and power is transferred from the wireless power transmitting apparatus 1 to the electronic device 2 without contact by the resonance. A magnetic field is changed by an AC current in a primary coil and current is induced to a secondary coil by the electromagnetic induction phenomenon to transfer power.

When the intensity of the current that flows on a primary coil of the wireless power transmitting apparatus 1 is changed, the magnetic field passing through the primary coil (or a transmitting Tx coil or a first coil) is changed by the current and the changed magnetic field generates induced electromotive force at a secondary coil (or a receiving Rx coil or a second coil) in the electronic device 2.

When the wireless power transmitting apparatus 1 and the electronic device 2 are disposed such that the transmission coil at the wireless power transmitting apparatus 1 and the receiving coil at the electronic device 2 come close to each other and the wireless power transmitting apparatus 1 controls the current of the transmission coil to be changed, the electronic device 2 may supply power to a load such as a battery by using the electromotive force induced to the receiving coil.

Efficiency of the wireless power transmission based on the inductive coupling scheme is influenced by a layout and a distance between the wireless power transmitting apparatus 1 and the electronic device 2. The wireless power transmitting apparatus 1 is configured to include a flat interface surface and a transmission coil is mounted on the bottom of the interface surface and one or more electronic devices may be laid on the top of the interface surface. By making the gap between the transmission coil mounted on the bottom of the interface surface and the receiving coil positioned on the top of the interface surface sufficiently small, the efficiency of the wireless power transmission by the inductive coupling method can be increased.

A mark indicating a location where the electronic device is to be laid may be displayed on the top of the interface surface of the wireless power transmitting apparatus. The mark may indicate the position of the electronic device which makes the arrangement between the primary coil mounted on the bottom of the interface surface and the secondary coil suitable. A protruded structure for guiding the location of the electronic device may be formed on the top of the interface surface. And a magnetic body may be formed on the bottom of the interface surface so that the primary coil and the secondary coil can be guided by an attractive force with a magnetic body of the other pole provided inside the electronic device.

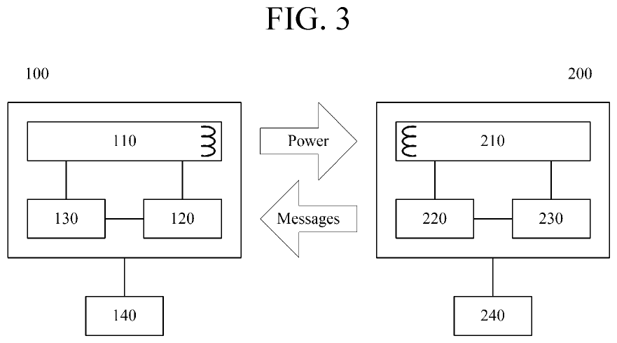

FIG. 2 conceptually illustrates a circuit configuration of a power conversion unit of a transmitting module for wirelessly transmitting power in an electromagnetic induction scheme.

The wireless power transmitting module may include a power conversion unit generally including a power source, an inverter, and a resonance circuit. The power source may be a voltage source or a current source and the power conversion unit converts the power supplied from the power source into a wireless power signal and transfers the converted wireless power signal to a power receiving module. The wireless power signal is formed in the form of the magnetic field or an electronic magnetic field having a resonance characteristic. And, the resonance circuit includes a coil generating the wireless power signal.

The inverter converts a DC input into an AC waveform having a desired voltage and a desired frequency through switching elements and a control circuit. And, in FIG. 2 a full-bridge inverter is illustrated and other types of inverters including a half-bridge inverter, and the like are also available.

The resonance circuit includes a primary coil Lp and a capacitor Cp to transmit power based on a magnetic induction scheme. The coil and the capacitor determine a basic resonance frequency of power transmission. The primary coil forms the magnetic field corresponding to the wireless power signal with a change of current and may be implemented in a flat form or a solenoid form.

The AC current converted by the inverter drives the resonance circuit, and as a result, the magnetic field is formed in the primary coil. By controlling the on/off timings of included switches, the inverter generates AC having a frequency close to the resonance frequency of the resonance circuit to increase transmission efficiency of the transmitting module. The transmission efficiency of the transmitting module may be changed by controlling the inverter.

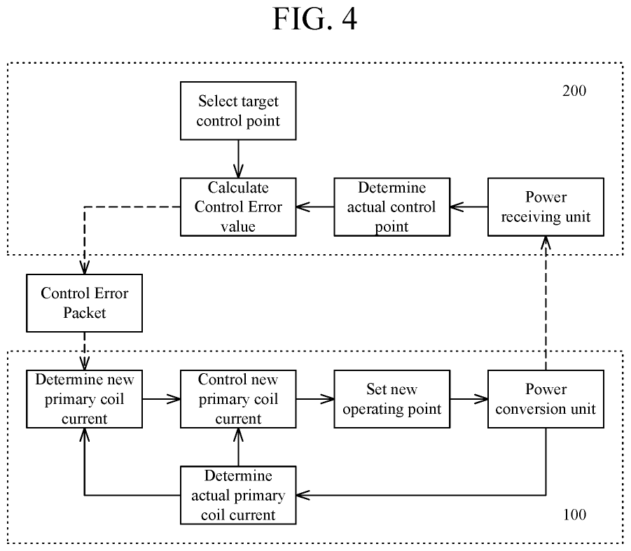

FIG. 3 illustrates a configuration for a wireless power transmitting module and a wireless power receiving module to send and receive power and messages.

Since the power conversion unit just transmits power unilaterally regardless of a receiving state of the receiving module, a configuration for receiving feedback associated with the receiving state from the receiving module is required in the wireless power transmission module in order to transmit power in accordance with the state of the receiving module.

The wireless power transmitting module 100 may include a power conversion unit 110, a communication unit 120, a control unit 130, and a power supply unit 140. And, the wireless power receiving module 200 may include a power receiving unit 210, a communication unit 220, and a control unit 230 and may further include a load 240 (or a power supply unit) to which received power is to be supplied. The load 240 may include a charging unit for charging an internal battery with power supplied from the power receiving unit 210.

The power conversion unit 110 includes the inverter and the resonance circuit of FIG. 2 and may further include a circuit to control characteristics including a frequency, voltage, current, and the like used to form the wireless power signal.

The communication unit 120, connected to the power conversion unit 110, may demodulate the wireless power signal modulated by the receiving module 200 wirelessly receiving power from the transmitting module 100 in the magnetic induction scheme, thereby detecting a power control message.

The control unit 130 determines one or more characteristics among an operating frequency, voltage, and current of the power conversion unit 110 based on the message detected by the communication unit 120 and controls the power conversion unit 110 to generate the wireless power signal suitable for the message. The communication unit 120 and the control unit 130 may be configured as one module.

The power receiving unit 210 may include a matching circuit, including the secondary coil and a capacitor, which generates the inductive electromotive force according to the change of the magnetic field generated from the primary coil of the power conversion unit 110, and may further include a rectification circuit that rectifies the AC current that flows on the secondary coil to output DC current.

The communication unit 220, connected to the power receiving unit 210, may change the wireless power signal between the transmitting module and the receiving module by adjusting the load of the power receiving unit in accordance with a method of adjusting a resistive load at DC and/or a capacitive load at AC to transmit the power control message to the transmitting module.

The control unit 230 of the receiving module controls individual components included in the receiving module. The control unit 230 may measure an output of the power receiving unit 210 in a current or voltage form and control the communication unit 220 based on the measured output to transfer the power control message to the wireless power transmitting module 100. The message may direct the wireless power transmitting module 100 to start or terminate the transmission of the wireless power signal and to control characteristics of the wireless power signal.

The wireless power signal formed by the power conversion unit 110 is received by the power receiving unit 210, and the control unit 230 of the receiving module controls the communication unit 220 to modulate the wireless power signal. The control unit 230 may perform a modulation process to change the amount of power received from the wireless power signal by changing the reactance of the communication unit 220. When the amount of power received from the wireless power signal is changed, a current and/or voltage of the power conversion unit 110 forming the wireless power signal is also changed and the communication unit 120 of the wireless power transmitting module 100 may sense the change in the current and/or voltage of the power conversion unit 110 and perform a demodulation process.

The control unit 230 generates a packet including a message to be transferred to the wireless power transmitting module 100 and modulates the wireless power signal to include the generated packet. The control unit 130 may acquire the power control message by decoding the packet extracted through the communication unit 120. The control unit 230 may transmit a message for requesting a change of the characteristic of the wireless power signal based on the amount of power received through the power receiving unit 210 in order to control to-be-received power.

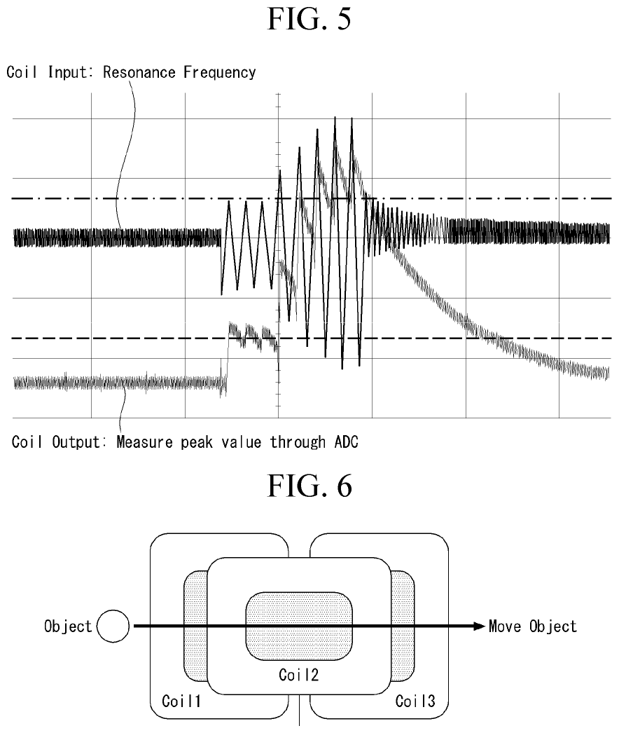

FIG. 4 is a block diagram of a loop for controlling power transmission between a wireless power transmitting module and a wireless power receiving module.

Current is induced in the power receiving unit 210 of the receiving module 200 according to the change of the magnetic field generated by the power conversion unit 110 of the transmitting module 100 and power is transmitted. The control unit 230 of the receiving module selects a desired control point, that is, a desired output current and/or voltage and determines an actual control point of the power received through the power receiving unit 210.

The control unit 230 calculates a control error value by using the desired control point and the actual control point while the power is transmitted and may take the difference between, for example, two output voltages or two output currents as the control error value. When less power is required to reach the desired control point, the control error value may be determined to be, for example, a minus value, and when more power is required to reach the desired control point, the control error value may be determined to be a plus value. The control unit 230 may generate a packet including the calculated control error value calculated by changing the reactance of the power receiving unit 210 with time through the communication unit 220 to transmit the packet to the transmitting module 100.

The communication unit 120 of the transmitting module detects a message by demodulating the packet included in the wireless power signal modulated by the receiving module 200 and may demodulate a control error packet including the control error value.

The control unit 130 of the transmitting module may acquire the control error value by decoding the control error packet extracted through the communication unit 120 and determine a new current value for transmitting power desired by the receiving module by using an actual current value which actually flows on the power conversion unit 110 and the control error value.

When the process of receiving the control error packet from the receiving device is stabilized, the control unit 130 of the transmitting module controls the power conversion unit 110 so that an operating point reaches a new operating point so an actual current value which flows on the primary coil becomes a new current value and a magnitude, a frequency, a duty ratio, or the like of an AC voltage applied to the primary coil becomes a new value. And, the control unit 130 controls the new operating point to be continuously maintained so as for the receiving device to additionally communicate control information or state information.

Interactions between the wireless power transmitting module 100 and the wireless power receiving module 200 may comprise four steps of selection, ping, identification and configuration, and power transfer. The selection step is a step for the transmitting module to discover an object laid on the surface of an interface. The ping step is a step for verifying whether the object includes a receiving module. The identification and configuration step is a preparation step for sending power to the receiving module during which appropriate information is received from the receiving module and a power transfer contract with the receiving module is made based on the received information. The power transfer step is a step of actually transmitting power to the receiving module wirelessly through the interaction between the transmitting module and the receiving module.

In the ping step, the receiving module 200 transmits a signal strength packet SSP indicating a magnetic flux coupling degree between a primary coil and a secondary coil through the modulation of a resonance waveform. The signal strength packet SSP is a message generated by the receiving module based on a rectified voltage. The transmitting module 100 may receive the message from the receiving module 200 and use the message to select an initial driving frequency for power transmission.

In the identification and configuration step, the receiving module 200 transmits to the transmitting module 100 an identification packet including a version, a manufacturer code, apparatus identification information, and the like of the receiving module 200, a configuration packet including information including maximum power, a power transmitting method, and the like of the receiving module 200, and the like.

In the power transmitting step, the receiving module 200 transmits to the transmitting module 100 a control error packet CEP indicating a difference between an operating point where the receiving module 200 receives a power signal and the operating point determined in the power transfer contract, a received power packet RPP indicating an average of the power which the receiving module 200 receives through the surface of the interface, and the like.

The received power packet RPP is the data about the amount of received power, which is obtained by taking a rectified voltage, a load current, an offset power, etc. of the power receiving unit 210 of the receiving device, and continuously transmitted to the transmitting module 100 while the receiving module 200 receives power. The transmitting module 100 receives the reception power packet RPP and uses it as an operation factor for power control.

The communication unit 120 of the transmitting module extracts the packets from change in resonance waveform, and the control unit 130 decodes the extracted packets to acquire the messages and controls the power conversion unit 110 based thereon to wirelessly transmit power while changing power transmission characteristics as the receiving module 200 requests.

Meanwhile, in a scheme that wirelessly transfers power based on inductive coupling, the efficiency is less influenced by frequency characteristics, but influenced by the arrangement and distance between the transmitting module 100 and the receiving module 200.

An area which the wireless power signal can reach may be divided into two. A portion of the interface surface through which a high efficiency magnetic field can pass when the transmitting module 100 wirelessly transmits power to the receiving module 200 may be referred to as an active area. An area where the transmitting module 100 can sense the existence of the receiving module 200 may be referred to as a sensing area.

The control unit 130 of the transmitting module may sense whether the receiving module is disposed in or removed from the active area or the sensing area. The control unit 130 may detect whether the receiving module 200 is disposed in the active area or the sensing area by using the wireless power signal formed in the power conversion unit 110 or using a separately provided sensor.

For example, the control unit 130 may detect whether the receiving module exists by monitoring whether the power characteristics for forming the wireless power signal is changed while the wireless power signal is being affected by the receiving module 200 existing in the sensing area. The control unit 130 may perform a process of identifying the receiving module 200 or determine whether to start wireless power transfer, according to a result of detecting the existence of the receiving module 200.

The power conversion unit 110 of the transmitting module may further include a position determination unit. The position determination unit may move or rotate the primary coil in order to increase the efficiency of the wireless power transfer based on the inductive coupling scheme and in particular, be used when the receiving module 200 does not exist in the active area of the transmitting module 100.

The position determination unit may include a driving unit for moving the primary coil so that a distance between the centers of the primary coil of the transmitting module 100 and the secondary coil of the receiving module 200 is within a predetermined range or so that the centers of the primary coil and the secondary coil overlap with each other. To this end, the transmitting module 100 may further include a sensor or a sensing unit for sensing the position of the receiving module 200. And the control unit 130 of the transmitting module may control the position determination unit based on the positional information of the receiving module 200, which is received from the sensor of the sensing unit.

Alternatively, the control unit 130 of the transmitting module may receive control information regarding the arrangement with or distance from the receiving module 200 through the communication unit 120 and control the position determination unit based on the control information.

Further, the transmitting apparatus 100 may include two or more primary coils to increase transmission efficiency by selectively using some primary coils arranged appropriately with the secondary coil of the receiving module 200 among the two or more primary coils. In this case, the position determination unit may determine which primary coils of the two or more primary coils are used for power transmission.

A single primary coil or a combination of one or more primary coils forming the magnetic field passing through the active area may be designated as a primary cell. The control unit 130 of the transmitting module may sense the position of the receiving module 200, determine the active area based on the determined active area, connect the transmitting module configuring the primary cell corresponding to the active area and control the primary coils of the transmitting module to be inductively coupled to the secondary coil of the receiving module 200.

Meanwhile, since the receiving module 200 is embedded in a smart terminal or an electronic apparatus such as a multimedia reproduction terminal or a smart phone and is laid in a direction or a location which is not constant in a vertical or horizontal direction on the surface of the interface of the transmitting module 100, the transmitting module requires a wide active area.

In case that a plurality of the primary coils are used in order to widen the active area, since a number of drive circuits equal to the number of the primary coils are required and the control over a plurality of primary coils is complicated, the cost of the transmitting module, that is, the wireless charger, is increased during commercialization. Further, in order to expand the active area, even when a scheme of changing the location of the primary coil is applied, since it is necessary to provide a transport mechanism for moving the location of the primary coil, there is a problem that a volume and a weight increase and manufacturing cost increases.

A method that extends the active area even with one primary coil of which the location is fixed is effective. However, when the size of the primary coil is just increased, a magnetic flux density per area decreases and magnetic coupling force between the primary coil and the secondary coil is weakened. As a result, the active area is not so increased as expected and the transmission efficiency is also lowered.

As such, it is important to determine an appropriate shape and an appropriate size of the primary coil in order to extend the active area and improve the transmission efficiency. A multi-coil scheme adopting two or more primary coils may be an effective method that extends the active area of the wireless power transmitting module.

Meanwhile, the operation of analog ping may be generally performed to determine whether an object or a foreign matter, particularly a metal foreign matter, is placed between the receiving device and the transmitting apparatus.

By the operation of analog ping, when a signal of a predetermined voltage is applied to a coil for a predetermined period of time at a resonant frequency and the coil is discharged, a change in the voltage of the coil over time may be measured to determine whether an object is present. The operation of digital ping may be a process of determining whether a receiving module is present after an object is sensed by the operation of analog ping and seeing whether there is a response from the receiving module by applying sufficient power to the coil to allow the receiving module to start.

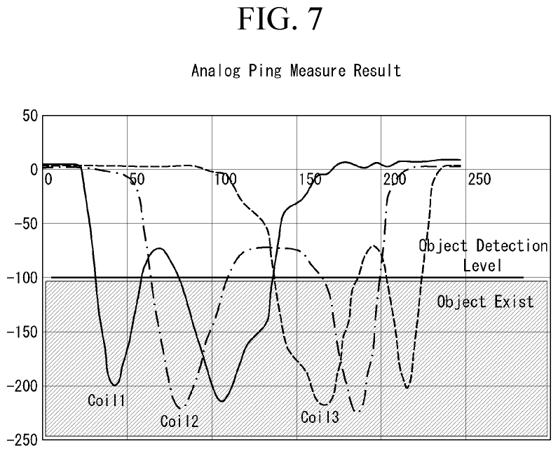

FIG. 5 shows coil input and output observed when performing the operation of analog ping in which a signal of a resonant frequency is input to a coil to obtain an output voltage of the coil by an ADC.

A resonant frequency may be applied to a coil in order to increase the efficiency of sensing an object during the operation of analog ping. In order to obtain a value of the resonant frequency, if a voltage is applied to both ends of the coil and the switch of the coil is turned on, resonance may occur in the coil, and an output signal of the coil may be converted into a square wave in the form of a pulse through a comparator to measure the period of the pulse.

As shown in FIG. 5, a predetermined voltage at a resonant frequency may be input to the coil, and the output voltage of the coil may be converted into a digital value by an ADC, thereby measuring a peak value of the output voltage as an analog ping value.

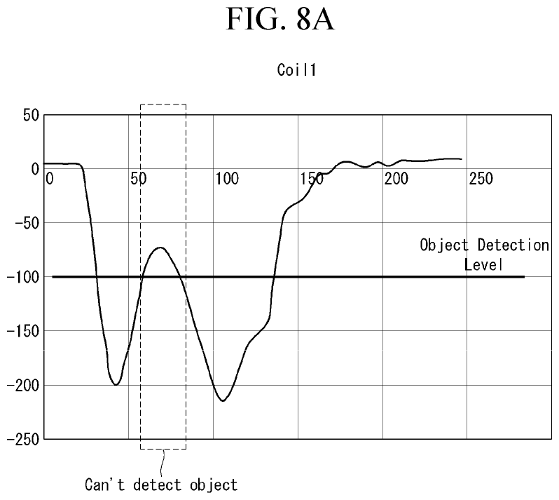

When an object is detected in a transmission coil employing multiple coils, the characteristics of an analog ping value depending on the positional relationship between the object and each coil may be grasped with reference FIGS. 6 to 8.

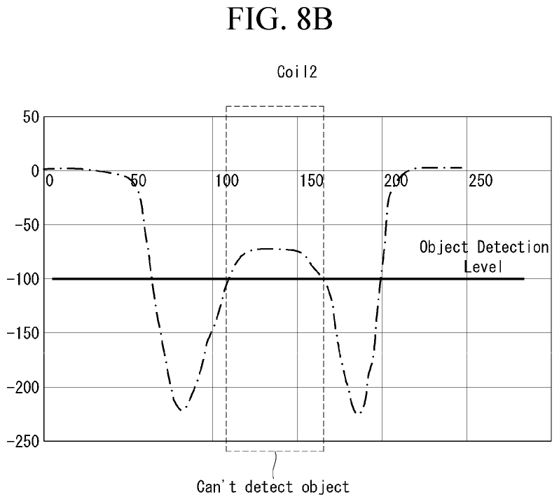

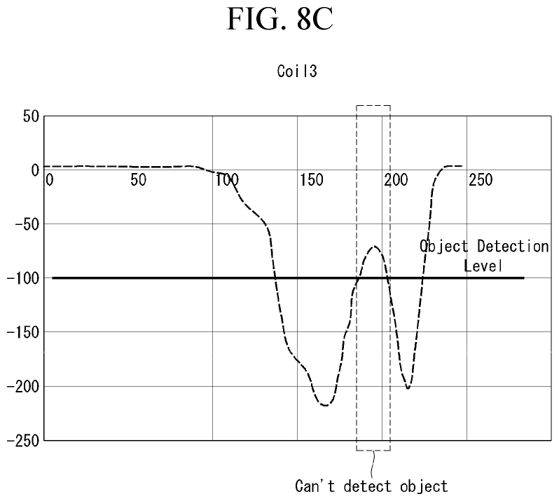

FIG. 6 shows an operation of measuring a resonant frequency and an analog peak voltage of each coil while moving an object through a transmission coil consisting of multiple coils, FIG. 7 shows a comparison of a peak voltage variation (analog ping variation) and an object detection level that have been measured in each coil by the operation in FIG. 6, and FIGS. 8A to 8C respectively show analog ping variations, object detection levels, and sections in which an object cannot be detected of first to third transmission coils.

In FIG. 6, coils 1, 2, and 3 (or a first coil, a second coil, and a third coil) as a transmission coil of a transmitting module are sequentially arranged with their portions overlapping each other in a horizontal direction. As shown in FIG. 6, while moving an object in the horizontal direction in which the coils 1, 2, and 3 are arranged, a resonant frequency may be supplied to each of the coils 1, 2, and 3 at each position of the object, and then the output voltage of each coil may be measured, thereby calculating an analog ping value of each coil.

In FIG. 7, the horizontal axis represents the displacement of an object moving in a horizontal direction from the left end to the right, and the vertical axis represents the amount of change in an analog ping value. That is, FIG. 7 shows the amount of change in an analog ping value measured when an object exists on the basis of an analog ping value measured when no object exists.

When there is an object, the output voltage of the coil may be reduced by the object, especially the metal object, so that, in FIG. 7, the amount of change in the analog ping value (hereinafter, referred to simply as an “analog ping variation”) may be expressed as a negative value and, as the analog ping variation becomes greater, the absolute value of the negative value becomes greater.

Since, on the horizontal axis, the coil 1 is on the left, the coil 2 is at the middle, and the coil 3 is on the right, on the graph for the coil 1 (see FIGS. 7 and 8A), that is, in the left section, an analog ping variation may occur first, then, on the graph for the coil 2 (see FIGS. 7 and 8B), that is, in the middle section, an analog ping variation may occur, and then, on the graph for the coil 3 (see FIGS. 7 and 8C), that is, in the right section, an analog ping variation may occur.

In FIGS. 7 and 8A to 8C, the amount of change rises and falls within the section where the analog ping variation occurs, that is, the section where there is apparently an object, which is because the diameter of the object used for measurement is smaller than the respective diameters of the coils 1 to 3.

When setting an object detection level, which is the criterion for determining that an object exists, to a predetermined value (a negative value based on 0), as shown in FIG. 7, a section in which the value of the analog ping variation is lower than the value of the object detection level may correspond to a section where there is apparently an object.

However, in some sections indicated by boxes in FIGS. 8A to 8C, even though there is an object, the value of the analog ping variation expressed as a negative value may be greater than the value of the object detection level, so that it may be erroneously determined that there is no object.

In FIGS. 8A to 8C, the section in which the value of the analog ping variation is greater than the value of the object detection level may generally correspond to a section in which an object is near the center of a corresponding coil, that is, in the area where the wire of the corresponding coil does not pass. However, because a wire of another coil adjacent to the corresponding coil may pass through the area, in the corresponding section of another coil, the value of the analog ping variation may be less than the value of the object detection level.

According to the present disclosure, since multiple coils may be disposed as mentioned above, it may be possible to increase the accuracy of detecting an object by comprehensively considering an analog ping value of each of the multiple coils. In other words, in the case of the wireless power transmitting apparatus having the transmission coil consisting of multiple coils, in order to prevent the problems that occur when whether there is an object is incorrectly determined based on an analog ping variation measured in each coil, whether there is an object may be determined by obtaining an analog ping value of each coil of the transmission coil, adding up these values to calculate the amount of variation of the added value, and comparing it with an object detection level.

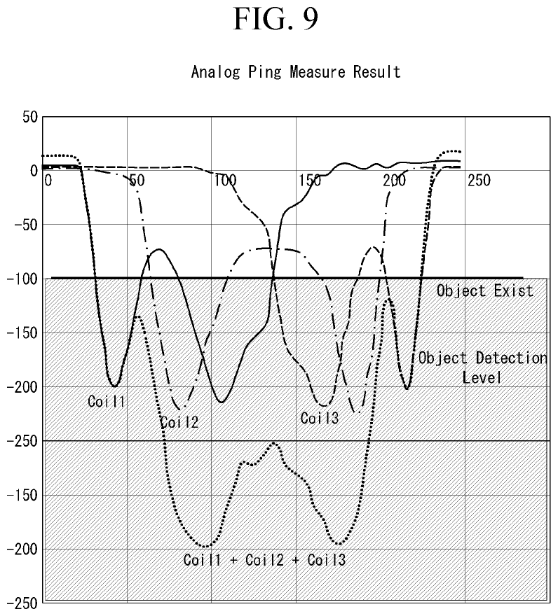

FIG. 9 shows the variation of the sum of analog ping values of the first to third coils and an object detection level.

In FIG. 9, the value of the variation (Coil 1+Coil 2+Coil 3) in the sum of the analog ping values measured in the coils 1 to 3 (hereinafter, referred to as an “analog ping sum variation”) is less than the value of the object detection level in the section from a first point on the left where the value of the analog ping variation of the coil 1 is less than the value of the object detection level to a second point on the right where the value of the analog ping variation of the coil 3 is less than the value of the object detection level. In this case, the first point and the second point correspond to the left end of the coil 1 and the right end of the coil 3, respectively.

Therefore, because the value of the analog ping sum variation may be less than the value of the object detection level regardless of where an object is placed in the transmission coil consisting of the multiple coils, it may be possible for the transmitting module consisting of the multiple coils to accurately detect an object by obtaining the value of the analog ping sum variation and comparing it with the value of the object detection level.

Meanwhile, when an object, that is, a metal foreign material, is placed on the surface of the interface above the transmission coil, and a predetermined voltage is applied to the transmission coil to drive the apparatus, the resonance frequency of the output voltage may be changed.

In consideration of this point, according to the present disclosure, it may be possible to determine whether there is an object based on the amount of change in a resonant frequency.

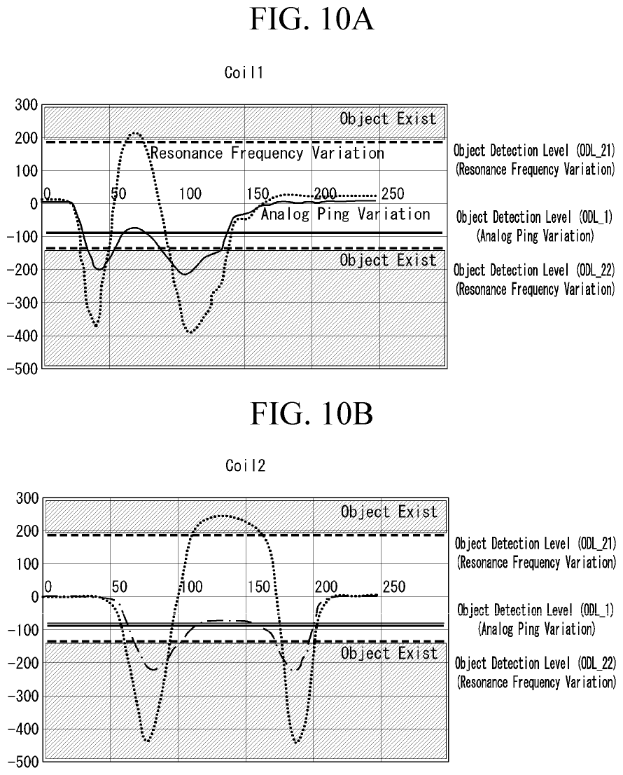

FIGS. 10A to 10C respectively show analog ping variations, resonance frequency variations, object detection levels for the analog ping variation, and object detection levels for the resonance frequency variation of the first to third transmission coils, which have been measured while moving an object as shown in FIG. 6.

In FIGS. 10A to 10C, the object detection level (ODL_1) is for comparison with the analog ping variation and may be referred to as an object detection level for analog ping, and the object detection levels (ODL_21 and ODL_22) are for comparison with the resonance frequency variation and may be referred to as an object detection level for a resonance frequency.

As shown in FIGS. 10A to 10C, while an object moves from one outer diameter of the coil to the opposite outer diameter, a resonance frequency measured from a signal sensed in the coil may also change. In addition, the curve representing the resonance frequency variation measured while moving the object may have a shape similar to that of the curve representing the analog ping variation measured in the coil, except for having positive values in some sections.

That is, while moving an object through the coil, a resonance frequency of a signal measured from the coil may be lower than the original resonance frequency when the object is in the section where wire strands forming the inner and outer diameters of one side of the coil are placed, the resonance frequency may be higher than the original resonance frequency when the object is in the center of the coil, i.e., the section without wires, and the resonance frequency may be lower than the original resonance frequency when the object is in the section where wire strands forming the opposite inner and outer diameters of the coil are placed.

Therefore, it may be possible to determine whether there is an object based on the resonance frequency variation, and, considering the fact that the resonance frequency variation may have positive or negative value depending on the position of the object, as shown in FIGS. 10A to 10C, an object detection level having a plus value (ODL_21) and an object detection level having a minus value (ODL_22) may be used as the object detection level (ODL) based on the resonance frequency variation.

When the value of the resonance frequency variation is greater than the value of the object detection level (ODL_21) (hereinafter, referred to as a “first object detection level for a resonance frequency”) having a positive value or is less than the value of the object detection level (ODL_22) (hereinafter, referred to as a “second object detection level for a resonance frequency”) having a negative value, it may be possible to determine that there is an object in the vicinity of a corresponding coil.

The wireless charger adopting multiple coils may detect an object based on a comparison of the analog ping variation obtained by performing the operation of analog ping on each of the multiple coils and the object detection level (ODL_1) for analog ping, may detect an object based on a comparison of the first and second object detection levels for a resonance frequency (ODL_21 and ODL_22) and the resonance frequency variation measured when driving each oil by applying a predetermined voltage thereto, or may detect an object based on a comparison of the variation in the sum of the analog ping values of the multiple coils, that is, the analog ping sum variation, and the object detection level for analog ping (ODL_1). Only one of these three methods may be used, or a combination of two or more thereof may be used.

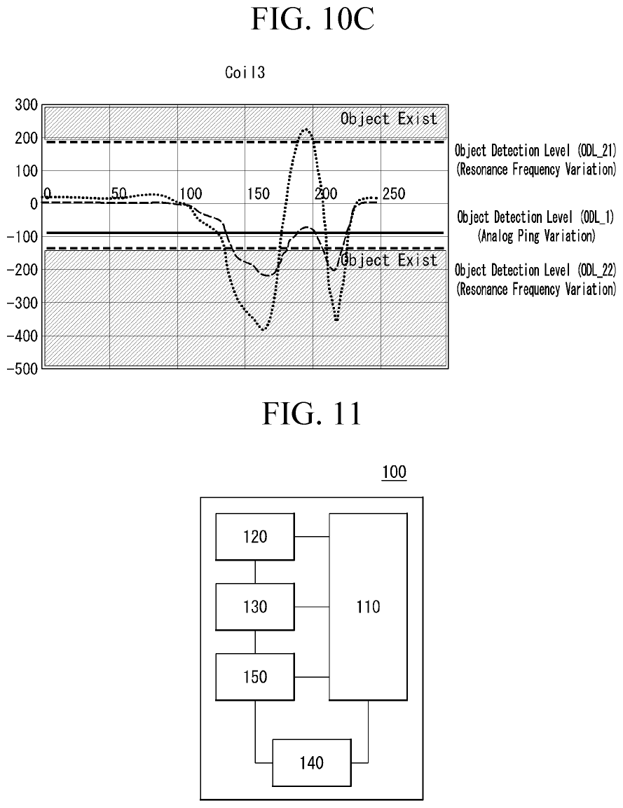

FIG. 11 is a block diagram of the wireless power transmitting apparatus according to the present disclosure.

The transmitting apparatus in FIG. 11 may further include a measurement unit for measuring an analog ping value and/or a resonant frequency in addition to the transmitting module shown in FIG. 3. In addition, the transmitting apparatus in FIG. 11 may further include a storage means for storing the original analog ping value (an analog ping value obtained when there is no foreign matter or receiving module) and the original resonance frequency (a resonant frequency obtained when there is no foreign matter or receiving module) of each coil and an output means for allowing a user to notice that an object other than a receiving module, that is, a metal foreign matter is placed thereon.

As shown in FIG. 11, The wireless power transmitting apparatus 100 or the transmitting module 100 may include the power conversion unit 110, the communication unit 120, the control unit 130, the power supply unit 140, and a measurement unit 150.

The power conversion unit 110 may consist of the inverter and the resonance circuit in FIG. 2 and may further include a circuit for adjusting characteristics such as frequency, voltage, and current used to form a wireless power signal.

The transmission coil (or the primary coil) of which the resonance circuit consists may consist of multiple coils, and portions of two or more or three or more of the coils may overlap each other.

The communication unit 120 connected to the power conversion unit 110 may detect a power control message by demodulating a wireless power signal modulated by a receiving device that wirelessly receives power according to magnetic induction. The communication unit 120 of the transmitting module capable of transmitting more than medium power may also communicate with a receiving module including a short-range communication means such as Bluetooth.

The control unit 130 may determine one or more of the operating frequency, voltage, and current of the power conversion unit 110 based on the messages detected by the communication unit 120, and may control the power conversion unit 110 to generate a wireless power signal suitable for the messages. The communication unit 120 and the control unit 130 may be formed as one module.

The power supply unit 140 may supply power to components of the transmitting apparatus.

The control unit 130 may control the power conversion unit 110 to perform the operation of analog ping of applying a predetermined voltage to each of the multiple coils at a resonance frequency of a corresponding coil (a resonant circuit including the corresponding coil), and, as a result of the operation of analog ping, the measurement unit 150 may obtain the voltage of the corresponding coil as an analog ping value.

In addition, the control unit 130 may control the power conversion unit 110 to turn on the inverter when a predetermined voltage is applied to each coil so that resonance may occur in the resonance circuit, and may measure a resonant frequency of a corresponding coil through the measurement unit 150.

The processor included in the control unit 130 may calculate the difference between an analog ping value of each coil measured by the operation of analog ping and the original analog ping value of the corresponding coil stored in a memory (not shown) to determine the analog ping variation of the corresponding coil, and, because the measured analog ping value may generally be less than the stored original analog ping value, the analog ping variation may have a negative value.

Furthermore, the processor of the control unit 130 may compare the measured resonant frequency of each coil with the original resonant frequency of the corresponding coil stored in a memory (not shown) to calculate the resonant frequency variation of the corresponding coil.

The processor of the control unit 130 may compare the analog ping variation of each coil with the object detection level (ODL_1) for analog ping stored in a memory to determine that an object is on the surface of the interface of the transmitting module when the value of the analog ping variation having a negative value is less than the value of the object detection level (ODL_1) for analog ping having a negative value and that there is no object otherwise.

In addition, the processor of the control unit 130 may compare the resonance frequency variation of each coil with the first and second object detection levels for a resonance frequency (ODL_21 and ODL_22) stored in a memory to determine that an object is on the surface of the interface of the transmitting module when the value of the resonance frequency variation is greater than the value of the first object detection level (ODL_21) having a positive value or less than the value of the second object detection level (ODL_22) having a negative value and that there is no object otherwise.

Furthermore, the processor of the control unit 130 may sum up analog ping variations of coils to obtain the analog ping sum variation and compare the analog ping sum variation with the object detection level for analog ping (ODL_1), and may determine that an object is on the surface of the interface of the transmitting module when the value of the analog ping sum variation having a negative value is less than the value of the object detection level for analog ping (ODL_1) having a negative value and that there is no object otherwise.

The power supply unit 140 may supply power to components of the transmitting apparatus.

The transmitting module 100 may further include an output unit (not shown) for allowing a user to notice that there is an object, for example, a metal foreign matter. The output unit may include at least one of a display unit outputting a message by an image or light, a sound unit delivering a message by sound, and a vibration unit delivering a message by vibration.

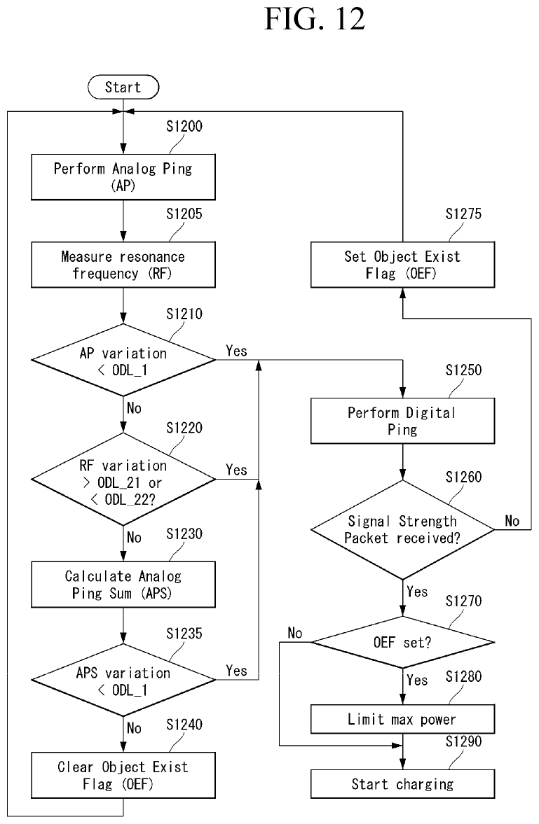

FIG. 12 is a flowchart of an operation of wirelessly transmitting power while detecting an object according to the present disclosure, and the operation in FIG. 12 may be performed by the control unit 130 of the transmitting apparatus or the processor included in the control unit 130.

The control unit 130 may control the power conversion unit 110 to perform the operation of analog ping on each of the multiple coils forming the primary coil included in the transmitting apparatus or the transmitting module 100, and may obtain an analog ping value of each coil through the measurement unit 150 at S1200.

In addition, the control unit 130 may calculate an analog ping variation (AP variation) of each coil based on a difference between an obtained analog ping value of a corresponding coil and an original analog ping value of the corresponding coil stored in a memory.

In order to calculate a resonant frequency variation (RF variation) of each coil, the control unit 130 may control the power conversion unit 110 to generate resonance in a resonance circuit of each coil and may measure a resonance frequency of a corresponding coil through the measurement unit 150 to compare it with an original resonance frequency of the corresponding coil stored in a memory at S1205. The order of the operation of analog ping and the operation of measuring a resonant frequency may be reversed.

The control unit 130 may compare an analog ping variation (AP variation) of one or more of multiple coils with the object detection level for analog ping (ODL_1) at S1210.

When, even for one coil, the value of an analog ping variation (AP variation) having a negative value is less than the value of the object detection level (ODL_1) for analog ping having a negative value (or the absolute value of the analog ping variation is greater than the absolute value of the object detection level for analog ping) (Yes in S1210), the control unit 130 may determine that there is an object on the surface of the interface of the transmitting apparatus 100 and proceed to S1250.

In contrast, when, for all coils, the value of an analog ping variation (AP variation) having a negative value is greater than the value of the object detection level (ODL_1) for analog ping having a negative value (or the absolute value of the analog ping variation is less than the absolute value of the object detection level for analog ping) (No in S1210), the control unit 130 may not determine that there is an object on the surface of the interface of the transmitting apparatus 100 and compare a resonant frequency variation (RF variation) of one or more of multiple coils with the first and second object detection levels for a resonance frequency (ODL_21 and ODL_22) at S1220.

When, even for one coil, the value of a resonance frequency variation (RF variation) is greater than the value of the first object detection level for a resonance frequency (ODL_21) having a positive value or is less than the value of the second object detection level for a resonance frequency (ODL_22) having a negative value (Yes in S1220), the control unit 130 may determine that there is an object on the surface of the interface of the transmitting apparatus 100 and proceed to S1250.

In contrast, when, for all coils, the value of a resonance frequency variation (RF variation) is less than the value of the first object detection level for a resonance frequency (ODL_21) having a positive value and is greater than the value of the second object detection level for a resonance frequency (ODL_22) having a negative value (No in S1220), the control unit 130 may not determine that there is an object on the surface of the interface of the transmitting apparatus 100, may obtain an analog ping sum APS by adding up analog ping values of multiple coils, and may compare it with the original analog ping value to calculate an analog ping sum variation (APS variation) at S1230.

When the value of an analog ping sum variation (APS variation) having a negative value is less than the value of the object detection level for analog ping (ODL_1) having a negative value (or the absolute value of the analog ping sum variation is greater than the absolute value of the object detection level for analog ping) (Yes in S1235), the control unit 130 may determine that there is an object on the surface of the interface of the transmitting apparatus 100 and proceed to S1250.

In contrast, when the value of an analog ping sum variation (APS variation) having a negative value is greater than the value of the object detection level for analog ping (ODL_1) having a negative value (or the absolute value of the analog ping sum variation is less than the absolute value of the object detection level for analog ping) (No in S1235), the control unit 130 finally may not determine that there is an object on the surface of the interface of the transmitting apparatus 100 and reset the value of an object exist flag (OEF) to a value of 0 at S1240.

S1220 of comparing a resonance frequency variation with the object detection level for a resonance frequency may also be taken after S1230 and S1235 of calculating an analog ping sum variation and comparing it with the object detection level for analog ping.

When it is determined that there is an object in at least one of S1210, S1220, and S1235, the control unit 130 may control the power conversion unit 110 to perform the operation of digital ping for applying sufficient power to start the receiving module to one or more of the multiple coils at S1250.

The control unit 130 may check whether a signal strength packet has been received from the receiving module by the operation of digital ping through the communication unit 120 at S1260.

When the signal strength packet has been received (Yes in S1260), that is, when it is determined that a receiving device is placed on the surface of the interface, the control unit 130 may check whether the value of the object exist flag (OEF) indicating whether a foreign matter other than a receiving device has been detected is set to 1 at S1270.

When the value of the object exist flag (OEF) is set to 1 (Yes in S1270), the control unit 130 may determine that there is a metal foreign matter as well as a receiving device on the surface of the interface of the transmitting apparatus 100 and limit the maximum amount of power wirelessly transmitted to the receiving device at S1280.

Thereafter, the control unit 130 may control the power conversion unit 110 and the communication unit 120 to perform a charging operation of wirelessly transferring power to a receiving device at S1290. Alternatively, when a receiving device is detected by receiving a signal strength packet and the value of the object exist flag (OEF) is set to 1 (Yes in S1270), the control unit 130 may stop transmitting power to the receiving device, and, in this case, S1290 may be skipped.

When not receiving a signal strength packet (No in S1260), the control unit 130 may not determine that there is a receiving device on the surface of the interface and a detected object is not a receiving device but a metal foreign matter and set the value of the object exist flag (OEF) to 1 at S1275.

Because it may be possible to detect an object only with an analog ping variation and an analog ping sum variation, the operation of measuring a resonance frequency in S1205 and the operation of comparing a resonance frequency variation with an object detection level in S1220 may be skipped.

As such, it may be possible for the wireless power transmitting apparatus adopting multiple coils to more accurately determine whether there is an object on the surface of the interface based on an analog ping variation, an analog ping sum variation, and a resonant frequency variation, determining whether to proceed or stop the operation of transmitting power (or charging) or whether to decrease the maximum amount of power to be transmitted.

In addition, in the event that an object, which is a metal foreign matter, is on the surface of the interface, it may be possible to provide a signal by an image, sound, etc. or stop transmitting power to prevent excessive heat or fire caused by the foreign matter. Furthermore, it may be possible to quickly charge an electronic device by preventing intermittent interruption of the charging operation by a foreign matter having little effect on charging.

The method of wirelessly transmitting power and the wireless power transmitting apparatus according to the present disclosure can be described as follows.

The method of wirelessly transmitting power according to an embodiment of the present disclosure may comprise performing an operation of analog ping on each of multiple coils of a primary coil; determining whether there is an object based on a result of the operation of analog ping; determining whether there is a receiving device including a secondary coil that can be coupled to the primary coil by magnetic induction by performing an operation of digital ping when it is determined that there is an object; and wirelessly transmitting power to a receiving device or stopping transmitting power thereto when it is determined that there is the receiving device. The step of determining whether there is an object may comprise: a first step of determining whether there is an object based on an analog ping variation obtained for each coil by the operation of analog ping; and a second step of determining whether there is an object based on an analog ping sum variation obtained by adding up the analog ping variation for each coil when it is not determined that there is an object in the first step.

According to an embodiment of the present disclosure, the first step may determine that there is an object when a value of the analog ping variation of at least one of the coils of the primary coil is less than a value of a first level having a negative value, and not determine that there is an object when the values of the analog ping variations of all the coils of the primary coil are greater than the value of the first level.

According to an embodiment of the present disclosure, the second step may determine that there is an object when a value of the analog ping sum variation is less than the value of the first level, and not determine that there is an object when the value of the analog ping sum variation is greater than the value of the first level.

According to an embodiment of the present disclosure, the step of determining whether there is an object may further comprise resetting an object exist flag when it is not determined that there is an object.

According to an embodiment of the present disclosure, the step of determining whether there is a receiving device may determine that there is a receiving device when a signal strength packet is received, and not determine that there is a receiving device when the signal strength packet is not received.

According to an embodiment of the present disclosure, the method may further comprise: the step of limiting the maximum amount of power that is transmitted to a receiving device when it is determined that there is the receiving device and the object exist flag is set.

According to an embodiment of the present disclosure, the step of wirelessly transmitting power or stopping transmitting power may stop power transmission when the object exist flag is set.

According to an embodiment of the present disclosure, the method may further comprise: setting the object exist flag when it is not determined that there is a receiving device.

According to an embodiment of the present disclosure, step of determining whether there is an object may further comprise: a third step of determining whether there is an object based on a measured resonance frequency variation of each of the coils of the primary coil when it is not determined that there is an object in the first step.

According to an embodiment of the present disclosure, the third step may determine that there is an object when a value of the resonance frequency variation of at least one of the coils of the primary coil is greater than a value of a second level having a positive value or less than a value of a third level having a negative value, and not determine that there is an object when values of resonance frequency variations of all the coils of the primary coil are less than the value of the second level and greater than the value of the third level.

The wireless power transmitting apparatus according to another embodiment of the present disclosure may comprise: a power conversion unit comprising an inverter for converting DC power to AC power and a resonant circuit including a primary coil consisting of multiple coils for transmitting power by being coupled, by magnetic induction, with a secondary coil of a receiving device; a measurement unit configured to measure an analog ping value as a result of an operation of analog ping; and a control unit configured to control the power conversion unit to perform the operation of analog ping on each of the coils of the primary coil, determine whether there is an object based on the analog ping value measured by the measurement unit, determine whether there is the receiving device by controlling the power conversion unit to perform an operation of digital ping when determining that there is an object, and control the power conversion unit to wirelessly transmit power to the receiving device or to stop power transmission when determining that there is the receiving device. The control unit may be further configured to determine whether there is an object based on an analog ping variation of each coil obtained by the operation of analog ping, and determine whether there is an object based on an analog ping sum variation obtained by adding up an analog ping variation of each coil when not determining that there is an object.

According to an embodiment of the present disclosure, the control unit is configured to determine that there is an object when a value of the analog ping variation of at least one of the coils of the primary coil is less than a value of a first level having a negative value, and not to determine that there is an object when the values of the analog ping variations of all the coils of the primary coil are greater than the value of the first level.

According to an embodiment of the present disclosure, the control unit is configured to determine that there is an object when a value of the analog ping sum variation is less than the value of the first level, and not to determine that there is an object when the value of the analog ping sum variation is greater than the value of the first level.

According to an embodiment of the present disclosure, the control unit is configured to control the power conversion unit to further determine whether there is an object based on a measured resonance frequency variation of each of the coils of the primary coil when not determining that there is an object based on the analog ping variation.

According to an embodiment of the present disclosure, the control unit is configured to reset an object exist flag when not determining that there is an object.

According to an embodiment of the present disclosure, when the control unit determines that there is a receiving device as it receives a signal strength packet during the operation of digital ping and sets the object exist flag, it is configured to limit the maximum amount of power that is transmitted to the receiving device.

According to an embodiment of the present disclosure, the control unit is configured to set the object exist flag when not determining that there is a receiving device as it does not receive a signal strength packet during the operation of digital ping.

Throughout the description, it should be understood by those skilled in the art that various changes and modifications are possible without departing from the technical principles of the present invention. Therefore, the technical scope of the present invention is not limited to the detailed descriptions in this specification but should be defined by the scope of the appended claims.

What is claimed is:

1. A method of wirelessly transmitting power, comprising:
performing an operation of analog ping on each of multiple coils of a primary coil;
determining whether there is an object based on a result of the operation of analog ping;
determining whether there is a receiving device including a secondary coil that can be coupled to the primary coil by magnetic induction by performing an operation of digital ping when it is determined that there is an object; and
wirelessly transmitting power to a receiving device or stopping transmitting power thereto when it is determined that there is the receiving device,
wherein the step of determining whether there is an object comprises:
a first step of determining whether there is an object based on an analog ping variation obtained for each coil by the operation of analog ping; and
a second step of determining whether there is an object based on an analog ping sum variation obtained by adding up the analog ping variation for each coil when it is not determined that there is an object in the first step.

2. The method of claim 1, wherein the first step determines that there is an object when a value of the analog ping variation of at least one of the coils of the primary coil is less than a value of a first level having a negative value, and does not determine that there is an object when the values of the analog ping variations of all the coils of the primary coil are greater than the value of the first level.

3. The method of claim 2, wherein the second step determines that there is an object when a value of the analog ping sum variation is less than the value of the first level, and does not determine that there is an object when the value of the analog ping sum variation is greater than the value of the first level.

4. The method of claim 1, wherein the step of determining whether there is an object further comprises: resetting an object exist flag when it is not determined that there is an object.

5. The method of claim 4, wherein the step of determining whether there is a receiving device determines that there is a receiving device when a signal strength packet is received, and does not determine that there is a receiving device when the signal strength packet is not received.

6. The method of claim 5, further comprising the step of limiting the maximum amount of power that is transmitted to a receiving device when it is determined that there is the receiving device and the object exist flag is set.

7. The method of claim 5, wherein the step of wirelessly transmitting power or stopping transmitting power stops power transmission when the object exist flag is set.

8. The method of claim 5, further comprising: setting the object exist flag when it is not determined that there is a receiving device.

9. The method of claim 1, wherein the step of determining whether there is an object further comprise: a third step of determining whether there is an object based on a measured resonance frequency variation of each of the coils of the primary coil when it is not determined that there is an object in the first step.

10. The method of claim 9, wherein the third step determines that there is an object when a value of the resonance frequency variation of at least one of the coils of the primary coil is greater than a value of a second level having a positive value or less than a value of a third level having a negative value, and does not determine that there is an object when values of resonance frequency variations of all the coils of the primary coil are less than the value of the second level and greater than the value of the third level.

11. A wireless power transmitting apparatus, comprising:
a power conversion unit comprising an inverter for converting DC power to AC power and a resonant circuit including a primary coil consisting of multiple coils for transmitting power by being coupled, by magnetic induction, with a secondary coil of a receiving device;
a measurement unit configured to measure an analog ping value as a result of an operation of analog ping; and
a control unit configured to control the power conversion unit to perform the operation of analog ping on each of the coils of the primary coil, determine whether there is an object based on the analog ping value measured by the measurement unit, determine whether there is the receiving device by controlling the power conversion unit to perform an operation of digital ping when determining that there is an object, and control the power conversion unit to wirelessly transmit power to the receiving device or to stop power transmission when determining that there is the receiving device,
wherein the control unit is further configured to determine whether there is an object based on an analog ping variation of each coil obtained by the operation of analog ping, and determine whether there is an object based on an analog ping sum variation obtained by adding up an analog ping variation of each coil when not determining that there is an object.

12. The wireless power transmitting apparatus of claim 11, wherein the control unit is configured to determine that there is an object when a value of the analog ping variation of at least one of the coils of the primary coil is less than a value of a first level having a negative value, and not to determine that there is an object when the values of the analog ping variations of all the coils of the primary coil are greater than the value of the first level.

13. The wireless power transmitting apparatus of claim 12, wherein the control unit is configured to determine that there is an object when a value of the analog ping sum variation is less than the value of the first level, and not to determine that there is an object when the value of the analog ping sum variation is greater than the value of the first level.

14. The wireless power transmitting apparatus of claim 11, wherein the control unit is configured to control the power conversion unit to further determine whether there is an object based on a measured resonance frequency variation of each of the coils of the primary coil when not determining that there is an object based on the analog ping variation.

15. The wireless power transmitting apparatus of claim 11, wherein the control unit is configured to reset an object exist flag when not determining that there is an object.

16. The wireless power transmitting apparatus of claim 15, wherein, when the control unit determines that there is a receiving device as it receives a signal strength packet during the operation of digital ping and sets the object exist flag, it is configured to limit the maximum amount of power that is transmitted to the receiving device.

17. The wireless power transmitting apparatus of claim 15, wherein the control unit is configured to set the object exist flag when not determining that there is a receiving device as it does not receive a signal strength packet during the operation of digital ping.
